(19) United States
(12) Patent Application Publication
(10) Pub. No.: US 2026/0198582 A1
(43) Pub. Date: Jul. 16, 2026

(54) Metal-Foam Vape Filter

(71) Applicant: CellMo Materials Innovation, Inc., Conroe, TX (US)

(72) Inventors: Sung-Mao Hung, Kaohsiung City (TW); Chia-Jung Kuo, New Taipei City (TW); Chih-Yung Chiang, Miaoli City (TW); Hyeseon Na, Seoul (KR); Heeman Choe, College Station, TX (US)

(21) Appl. No.: 19/137,626

(22) PCT Filed: Dec. 12, 2023
(86) PCT No.: PCT/US2023/083701

§ 371 Date: Jun. 10, 2025

Related U.S. Application Data
(60) Provisional application No. 63/432,017, filed on Dec. 12, 2022.

(51) Int. Cl. A24F 40/46; A24F 40/10; A24F 40/70

(52) U.S. Cl. CPC A24F 40/46; A24F 40/10; A24F 40/70

(57) ABSTRACT

A metal foam vape structure is used for fluid filtration or purification, such as vapor or gas filtration. It is also used for inhaling and exhaling vapor containing nicotine and flavoring produced by a device. This metal foam structure can thus be used in electronic cigarettes or ecigarettes and related devices.

### CROSS-REFERENCE TO RELATED APPLICATIONS

This application claims the benefit of U.S. patent application 63/432,017, filed Dec. 12, 2022.

### BACKGROUND OF THE INVENTION

This invention relates to fluid filtration, and more specifically to a metal foam structure for a vaporizer filter (also referred to as a vape filter) and techniques of making and using a metal-foam vaporizer filter, such as for use in electronic cigarettes or e-cigarettes, nicotine vapes, cannabis vapes, and similar and related devices.

There is a need for improved vaporizer filters or vape filters, especially using metal foam.

### Brief Summary of the Invention

A metal foam structure is used for fluid filtration or purification, such as vapor or gas filtration. This metal foam structure can be used in electronic cigarettes or e-cigarettes and related devices.

In an implementation, a device includes a metal-foam vape filter.

In an implementation, a device includes a metal-foam vape filter having a metal-oxide-foam portion and a metal-foam heater portion, where the metal-foam heater portion is coupled to the metal-oxide-foam portion.

In an implementation, a method includes: forming a metal-oxide foam block; forming a metal-foam block; forming a plurality of pads on the on the metal-foam block; and attaching the metal-foam block to a surface of the metal-oxide foam block.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows a structure of an e-cigarette or similar device.

FIG. 2 shows a metal-foam filter, which can be used in an e-cigarette, in comparison with a traditional ceramic filter containing a steel wire patterned heater.

FIG. 3 shows a cross-sectional, schematic view of a metal-foam filter.

FIG. 4 shows optical images of titanium and titanium oxide foam filters before and after heat treatment, respectively.

FIG. 5 shows schematic diagram examples of zigzag-type or serpentine-type metal-foam electric heaters with different pattern widths.

FIG. 6 shows optical images of final metal-foam vape filter products including nonconductive titanium oxide foam filter and nickel foam electric heater with two copper foil pads attached.

### DETAILED DESCRIPTION OF THE INVENTION

E-cigarettes are sometimes called “e-cigs,” “vapes,” “e-hookahs,” “vape pens,” and “electronic nicotine delivery systems.” Some e-cigarettes look like regular cigarettes, cigars, or pipes. Some look like USB flash drives, pens, and other everyday items.

This patent describes some examples of implementations with specific dimensions, measurements, temperatures, and values. These are not intended to be exhaustive or to limit the invention to the precise form described. The values, percentages, times, and temperatures are approximate values. These values can vary due to, for example, measurement or manufacturing variations or tolerances or other factors. For example, depending on the tightness of the manufacturing and measurement tolerances, the values can vary plus or minus 5 percent, plus or minus 7.5 percent, plus or minus 10 percent, plus or minus 12.5 percent, plus or minus 15 percent, plus or minus 17.5 percent, plus or minus 20 percent, or plus or minus 25 percent.

Further, the values are for a specific implementation, and other implementations can have different values, such as certain values made larger for a larger-scaled process or product, or smaller for a smaller-scaled product. A device, apparatus, or process may be made proportionally larger or smaller by adjusting relative measurements proportionally (e.g., maintaining the same or about the same ratio between different measurements). In various implementations, the values can be the same as the value given, about the same of the value given, at least or greater than the value given, can be at most or less than the value given, or between any of the values given (inclusive or exclusive), or any combination of these.

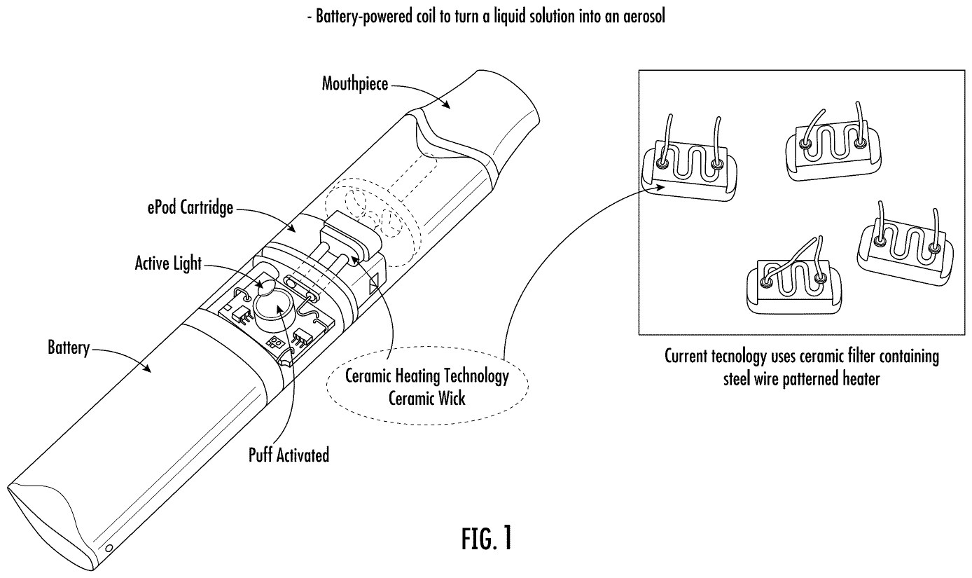

FIG. 1 shows an example of a common structure of an e-cigarette or similar device. The e-cigarette includes a battery, active light, ePod cartridge, mouthpiece, and ceramic heating element or ceramic wick. The ceramic heating element has a ceramic filter with a steel wire patterned heater element on a surface of the element.

In an e-cigarette device, a battery-powered coil turns a liquid solution into an aerosol. The liquid solution can contain nicotine, cannabis, flavorings, or fragrances, in any combination. The liquid is atomized by way of an atomizer, such as a piezo atomizer.

For example, piezo atomizers are used to atomize the liquid solution, creating and dispensing a mist. The fluid solution is placed in a reservoir, surrounded by a piezo element, usually a piezo disc. A perforated mesh disc with many tiny holes is places on top of the liquid reservoir and piezo element. When an electrical voltage is applied to a piezo atomizer, the piezo element generates ultrasonic frequencies. The rapid ultrasonic vibration from the piezoceramic causes the fluid to be pushed through the mesh disc, producing tiny droplets or mist. The micron-size droplets produced by the piezoelectric atomizer can be uniform in size and distribution due to the mesh disc. The number of holes and size of holes in the mesh disc determines the droplet size and flow rate.

The heating element heats the ceramic filter, and which heats the mist that passes through the filter. Then the mist that is inhaled by the user will be warmed by the heating element.

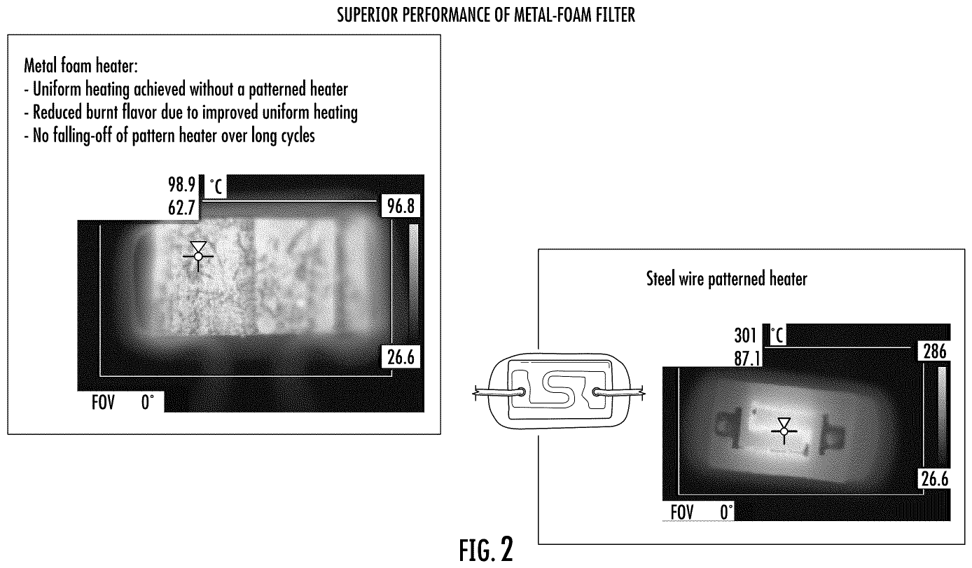

FIG. 2 shows a metal-foam filter, which can be used in an e-cigarette, in comparison with a traditional ceramic filter containing a steel wire patterned heater. U.S. patent applications 62/194,564, filed Jul. 20, 2015, Ser. No. 15/215,519, filed Jul. 20, 2016, 62/194,677, filed Jul. 20, 2015, Ser. No. 15/215,541, filed Jul. 20, 2016, 62/641,223, filed Mar. 9, 2018, PCT/US2019/021704, filed Mar. 11, 2019, 61/700,793, filed Jul. 19, 2018, and PCT/US2019/042686, filed Jul. 19, 2019 are incorporated by reference. These applications describe techniques of manufacturing a metal foam. These techniques, in whole or in part, can be used to manufacture a metal foam that is used for a vaporizer filter.

The metal form structure has a metal foam heater formed on a surface of the metal foam structure. With the metal foam heater, uniform heating is achieved without patterned heater. Additionally, there will be reduced burnt flavor owing to the uniform heating achieved using the metal foam heater, along with no falling-off of steel wire patterned heater over long cycles.

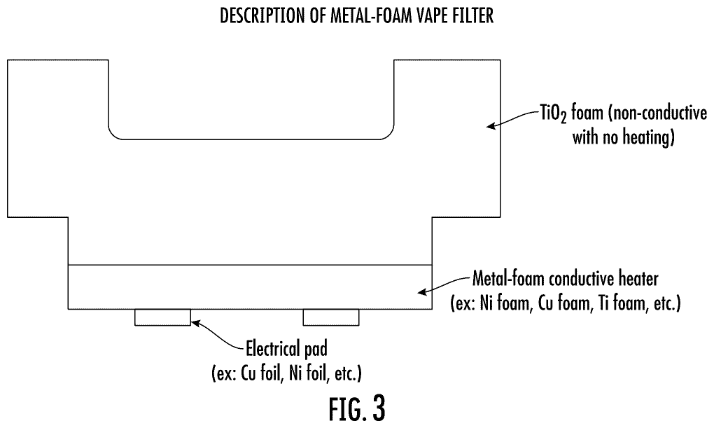

FIG. 3 shows a cross-sectional, schematic view of a metal-foam filter. A first portion of the metal-foam structure includes a titanium oxide foam, aluminum nitride, or aluminum oxide, which is nonconductive and does not include heating (e.g., no heating element). A second portion of the metal-foam structure includes a conductive metal foam heater, such as nickel foam, copper foam, titanium foam, and others. An electrical pad (e.g., such as copper foil or other conductor) is also formed on a surface of the conductive metal foam heater.

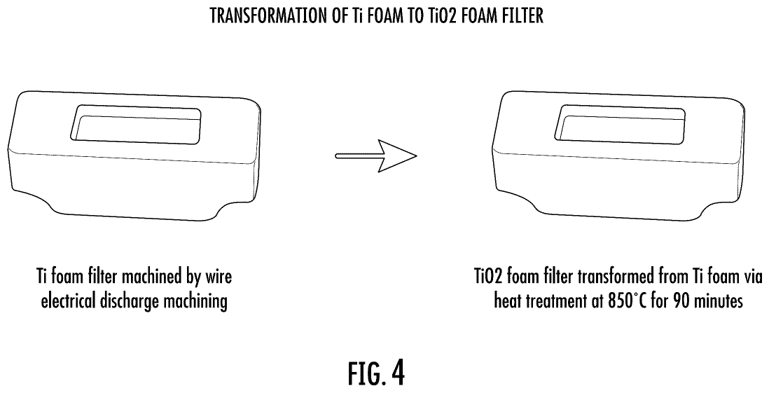

FIG. 4 shows optical images of titanium and titanium oxide foam filters before and after heat treatment, respectively. A titanium metal-foam filter is transformed by chemical processing into a titanium-oxide metal-foam filter. A titanium foam filter is machined by wire electrical discharge machining. A titanium foam filter is transformed from titanium foam (conductive) via heat treatment at about 850 degrees Celsius for about 90 minutes in air into titanium oxide (nonconductive).

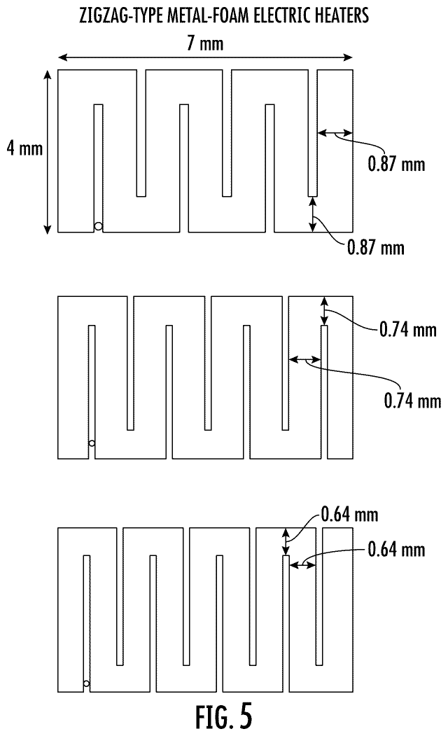

FIG. 5 shows schematic diagram examples of zigzag-type or serpentine-type metal-foam electric heaters with different pattern widths. The zigzag-type metal-foam electric heaters can be made of either copper or nickel foams. Depending on the desired resistance of the metal-foam electric heaters, the porosity and the pattern width can be adjusted.

For example, a first implementation is provided in a rectangular area of about 4 millimeters by 7 millimeters. A layout of the metal-foam heater is a serpentine structure having six 180-degree turns. A width of the metal-foam is 0.87 millimeters.

As another example, a second implementation is also provided in a rectangular area of about 4 millimeters by 7 millimeters. A layout of the metal-foam heater is a serpentine structure having seven 180-degree turns. A width of the metal-foam is 0.74 millimeters. A total length of the second serpentine implementation is greater than the first serpentine implementation. Therefore, the second serpentine implementation has a greater number of squares of resistance than the first serpentine implementation.

As a further example, a third implementation is also provided in a rectangular area of about 4 millimeters by 7 millimeters. A layout of the metal-foam heater is a serpentine structure having eight 180-degree turns. A width of the metal-foam is 0.64 millimeters. A total length of the third serpentine implementation is greater than the second serpentine implementation. Therefore, the third serpentine implementation has a greater number of squares of resistance than the second serpentine implementation.

An implementation is selected from the first, second, and third implementations to provide the desired resistance to achieve a desired temperature setting for an electric heater for the device.

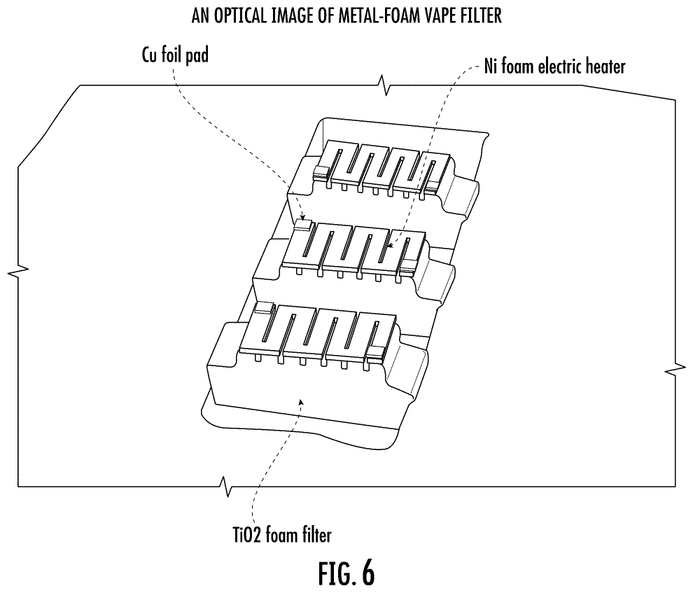

FIG. 6 shows optical images of final metal-foam vape filter products including nonconductive titanium oxide foam filter and nickel foam electric heater with two copper foil pads attached. These filters use a nickel foam electric heater having a serpentine structure, such as from FIG. 5. This serpentine electric heater is formed on and is thermally coupled to a surface of a titanium foam filter. Formed at ends of the serpentine structures are copper foil pads, which are used as electrodes for electrical connections.

The serpentine structure can be attached to the foam filter by, for example, brazing, welding, or soldering. For example, in an implementation, the bonding of the nickel foam electric heater was conducted at about 865 degrees Celsius for about 5 hours in a nitrogen atmosphere. Copper powder was lightly distributed between the nickel foam heater and the titanium oxide foam filter to facilitate the bonding.

In an implementation, a device, such as an e-cigarette, includes metal-foam vape filter. The metal-foam vape filter includes a titanium oxide or titanium dioxide (TiO2) ceramic foam that is bonded with nickel (Ni) foam and copper (Cu) foil pads, which act as electrical heater. The TiO2 ceramic foam is transformed from titanium (Ti) foam via a heat treatment after being machined into the desired shape. The Ni foam and Cu foil pads are bonded to the TiO2 ceramic foam via a heat treatment under a pressure. The heat-treatment bonding between the ceramic foam and the metal foam is facilitated using a bonding agent such as copper powder or paste. A synthesis method of the titanium oxide and nickel foams includes a combination of slurry freezing, drying, and thermal sintering.

In an implementation, a method of forming a metal-foam vape filter includes: creating a titanium oxide (TiO2) ceramic foam and bonding the ceramic foam with nickel (Ni) foam, and bonding the nickel foam with copper (Cu) foil pads. The titanium oxide ceramic foam is transformed from titanium foam via a heat treatment after being machined into the desired shape. The nickel foil and copper foil pads are bonded to the titanium oxide ceramic foam via a heat treatment under a pressure. The heat-treatment bonding between the ceramic foam and the metal foam is facilitated using a bonding agent such as copper powder or paste. A synthesis method of the titanium oxide and nickel foams includes a combination of slurry freezing, drying, and thermal sintering.

In an implementation, a method of forming a metal-foam vape filter includes: forming a first foam; forming a second foam; bonding the first foam to the second foam; and forming electrical contacts on the second foam. The first foam is an insulating foam (or nonconducting foam) while the second foam is a conductive foam. The first foam is formed by: forming a titanium foam, and using a heat treatment, transforming the titanium foam into titanium oxide foam, where the titanium oxide foam is the first foam. Bonding the second foam to the first foam is performed via a heat treatment under a pressure. Additionally, bonding electrical contacts on the second foam is performed via a heat treatment under a pressure. The second foam can be nickel foam. The electrical contacts can be copper foil pads. A heat-treatment bonding between the first foam (e.g., a ceramic foam) and the second foam (e.g., a metal foam) is facilitated using a bonding agent such as a conductive powder or paste (e.g., copper powder or paste). To manufacture the first foam (e.g., titanium oxide foam) and second foam (e.g., nickel foam), a synthesis method can used, which can include any combination of slurry freezing, drying, and thermal sintering.

In an implementation, a device includes a metal-foam vape filter including a metal-oxide-foam portion and a metal-foam heater portion. The metal-foam heater portion is attached to the metal-oxide-foam portion. A liquid material is contained in or otherwise coupled to or drawn through the metal-oxide-foam filter portion of the vape filter. This liquid is heated and vaporized by the metal-foam heater portion.

In various implementations, the metal-oxide-foam portion includes a titanium dioxide foam. The metal-foam portion includes at least one of a nickel foam, aluminum foam, copper foam, or titanium foam. The device further includes electrical pads attached to or formed on the metal-foam heater portion. The electrical pads supply power to the metal-foam heater, which cause the resistive heater to heat up. The metal-oxide-foam filter is a nonconductive ceramic foam filter such as titanium oxide (TiO2), copper oxide (CuO), nickel oxide (NiO), silicon carbide (SiC), aluminum oxide (Al2O3), silicon oxide (SiO2), or others.

The metal-foam heater portion includes nickel foam, aluminum foam, titanium foam, or copper foam. The metal-foam heater portion can be a plain sheet (e.g., rectangular or square sheet) or patterned in a zigzag or serpentine shape, which generally would increase a number of squares of resistance for a given area. The metal-foam heater portion will have nickel of copper pads at ends of the heater shape. A thickness of the metal-foam heater portion will be between about 100 microns and 300 microns.

In an implementation, a method includes: forming a metal-oxide foam block; forming a metal-foam block; forming a plurality of pads on the metal-foam block; and attaching the metal-foam block to a surface of the metal-oxide foam block.

The metal-foam block includes at least one of nickel foam, aluminum foam, titanium foam, or copper foam, and a zigzag or serpentine pattern. The pads can be nickel or copper, the metal-oxide foam can be titanium oxide, and the method includes bonding the pads to the metal-foam block via a heat treatment at a temperature of about 600 degrees Celsius to about 1100 degrees Celsius for about 10 minutes to about 10 hours in at least one of argon or nitrogen gas atmosphere.

Forming a metal-oxide foam block can include: machining a titanium foam starting material into a desired shape; transforming the machined titanium foam via a heat treatment at a temperature of about 300 degrees Celsius to about 1100 degrees Celsius for about 10 minutes to about 10 hours to obtain a titanium-oxide-foam block; and using the titanium-oxide-foam block as the a metal-oxide foam block. The machined titanium foam can include a recessed region on a first side and an elevated region on a second side. The second side is opposite of the first side. The metal-foam block is attached to the elevated region of the titanium-oxide-foam block.

The method can include forming a heat-treatment bonding between the titanium-oxide-foam block and the metal-foam block (including, for example, nickel) using a bonding agent including at least one of copper powder or paste, or nickel powder or paste. The method can include forming a metal-foam block using a combination of one or more of powder slurry freezing, drying, or thermal sintering; and transforming the metal-foam block into the metal-oxide foam block. The method can include forming the metal-foam block using a combination of one or more of powder slurry freezing, drying, and thermal sintering.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. A device comprising a metal-foam vape filter.

2. The manufacture of claim 1 wherein TiO2 ceramic foam is bonded with Ni foam and Cu foil pads, which act as electrical heater.

3. The manufacture of claim 1 wherein TiO2 ceramic foam is transformed from Ti foam via a heat treatment after being machined into the desired shape.

4. The manufacture of claim 1 wherein Ni foam and Cu foil pads are bonded to TiO2 ceramic foam via a heat treatment under a pressure.

5. The manufacture of claim 1 wherein the heat-treatment bonding between the ceramic foam and the metal foam is facilitated using a bonding agent such as Cu powder or paste.

6. The manufacture of claim 1 wherein a synthesis method of the TiO2 and Ni foams comprises a combination of the slurry freezing, drying, and thermal sintering.

7. A device comprises:
a metal-foam vape filter comprising a metal-oxide-foam portion and a metal-foam heater portion, wherein the metal-foam heater portion is coupled to the metal-oxide-foam portion.

8. The device of claim 7 wherein a liquid material contained in the metal-oxide-foam filter portion of the vape filter is heated and vaporized by the metal-foam heater portion.

9. The device of claim 7 wherein the metal-oxide-foam portion comprises a titanium dioxide foam.

10. The device of claim 7 wherein the metal-foam portion comprises at least one of a nickel foam, aluminum foam, copper foam, or titanium foam.

11. The device of claim 7 comprising electrical pads coupled to the metal-foam heater portion.

12. The device of claim 7 wherein the metal-oxide-foam filter is a nonconductive ceramic foam filter comprising titanium oxide (TiO2), copper oxide (CuO), nickel oxide (NiO), silicon carbide (SiC), aluminum oxide (Al2O3), or silicon oxide (SiO2).

13. The device of claim 7 wherein the metal-foam heater portion comprises at least one of nickel foam, aluminum foam, titanium foam, or copper foam in the form of plain sheet or zigzag or serpentine pattern further comprising at least two nickel or copper foil pads coupled to the metal-foam heater portion.

14. The device of claim 13 wherein a thickness of the metal-foam heater portion is between about 100 microns and 300 microns.

15. A method comprising:
forming a metal-oxide foam block;
forming a metal-foam block;
forming a plurality of pads on the metal-foam block; and
coupling the metal-foam block to a surface of the metal-oxide foam block.

16. The method of claim 15 wherein the metal-foam block comprises at least one of nickel foam, aluminum foam, titanium foam, or copper foam, and a zigzag or serpentine pattern.

17. The method of claim 15 wherein the pads comprise at least one of nickel or copper, and the metal-oxide foam comprises titanium oxide, and the method comprises
bonding the pads to the metal-foam block via a heat treatment at a temperature of about 600 degrees Celsius to about 1100 degrees Celsius for about 10 minutes to about 10 hours in at least one of argon or nitrogen.

18. The method of claim 15 wherein the forming a metal-oxide foam block comprises:
machining a titanium foam starting material into a desired shape;
transforming the machined titanium foam via a heat treatment at a temperature of about 300 degrees Celsius to about 1100 degrees Celsius for about 10 minutes to about 10 hours to obtain a titanium-oxide-foam block; and
using the titanium-oxide-foam block as the metal-oxide foam block.

19. The method of claim 18 wherein the machined titanium foam comprises a recessed region on a first side and an elevated region on a second side.

20. The method of claim 19 wherein the second side is opposite of the first side.

21. The method of claim 19 wherein the metal-foam block is coupled to the elevated region of the titanium-oxide-foam block.

22. The method of claim 15 comprising:
forming a heat-treatment bonding between the titanium-oxide-foam block and the metal-foam block, comprising nickel, using a bonding agent comprising at least one of copper powder or paste, or nickel powder or paste.

23. The method of claim 15 comprising:
forming a metal-foam block using a combination of one or more of powder slurry freezing, drying, or thermal sintering; and
transforming the metal-foam block into the metal-oxide foam block.

24. The method of claim 15 comprising:
forming the metal-foam block using a combination of one or more of powder slurry freezing, drying, and thermal sintering.
